(19) United States
(12) Patent Application Publication
(10) Pub. No.: US 2024/0308129 A1
(43) Pub. Date: Sep. 19, 2024

(54) PROCESSING APPARATUS SEPARATING MULTILAYER MATERIAL, PROCESSING METHOD, AND METHOD FOR MANUFACTURING ARTICLE USING PROCESSING APPARATUS

(71) Applicant: CANON KABUSHIKI KAISHA, Tokyo (JP)

(72) Inventor: YUSHI YAMAKAWA, Tochigi (JP)

(21) Appl. No.: 18/601,848

(22) Filed: Mar. 11, 2024

(30) Foreign Application Priority Data
Mar. 14, 2023 (JP) 2023-040175

(51) Int. Cl. B29C 59/00; B29C 59/02; B32B 43/00; H01L 21/027

(52) U.S. Cl. CPC B29C 59/002; B32B 43/006; B29C 59/026; H01L 21/027

(57) ABSTRACT

A processing apparatus configured to separate a multilayer material in which a curable composition is sandwiched between a first member and a second member facing each other, includes a first holding unit configured to suction and hold a first surface of the multilayer material, a second holding unit configured to suction and hold a second surface facing the first surface of the multilayer material, and a deformation mechanism, wherein at least one of the first holding unit and the second holding unit is configured to suction and hold the multilayer material via a flexible member, and wherein the deformation mechanism is configured to deform at least a portion of the flexible member so as to form a start point of separation in the multilayer material.

### BACKGROUND

### Field of the Disclosure

The present disclosure relates to a processing apparatus that separates a multilayer material in which a curable composition is sandwiched. The present disclosure also relates to a method for manufacturing an article using the processing apparatus.

### Description of the Related Art

As semiconductor elements continue to miniaturize, a nano imprint lithography (hereinafter referred to as imprinting) technique is being put into practical use as a technique that enables production of microstructural devices using design rules on a nanometer order and is suitable for mass production. In the imprinting technique, masks (also referred to as molds or templates) having an uneven surface structure on a nanometer scale are used as molding dies. The masks are fabricated by using an electron beam drawing apparatus or a semiconductor exposure apparatus. In a state where a molding die is pressed against a curable composition on a substrate, the curable composition is cured so that a pattern of the molding die is transferred to the curable composition. An example of a method for curing the curable composition is a photo-curing method. A photocurable composition is supplied to a shot region on a substrate, and the composition is irradiated with light in a state of being molded in a molding die to cure the composition. The molding die is released from the cured composition to form a pattern of a cured material on the substrate.

In an imprint apparatus that forms a pattern, mainly, a step-and-repeat method is used by which an imprinting process is repeated for each shot region to form a pattern for one substrate. In addition, in order to improve a throughput, there has been proposed a batch imprinting method by which a molding die of a size as large as the substrate is used to form a pattern for one substrate by one imprinting process.

In recent years, as a form of imprint apparatus, there has been discussed a technique for flattening a curable composition dropped onto a substrate using a flat molding die (also referred to as a template or super straight) (see Japanese Patent No. 5349588). The technique discussed in Japanese Patent No. 5349588 is intended to improve the accuracy of flattening by dropping the curable composition by an amount adjusted based on the uneven surface structure of the substrate and curing the composition in a state where the flat template is in contact with the dropped composition.

In these imprint apparatuses, when the template is separated (hereinafter referred to as released) from a cured composition (cured material), a force of resisting to releasing, i.e., a mold release force is generated. Particularly, in the batch imprinting method, since the area of contact between the template and the cured material is large, the mold release force becomes very large. Thus, it is effective to provide a means of forming a start point of releasing at the start of releasing. A similar issue is recognized in separation of bonded wafers. U.S. Pat. No. 8,845,859 discusses a means of forming the start point of releasing by inserting a blade into a bonded surface between the bonded wafers.

However, in the case of forming the start point of releasing by mechanical contact, there is a concern about dust generation due to the contact between a mechanical element and a template or a substrate. The generated dust may stick to the substrate or the template. The dust sticking to the substrate or the template may cause a defect in the device, which may lead to device failure.

### SUMMARY

In view of this, the present disclosure is directed to providing a processing apparatus that is advantageous in forming the start point of separation while preventing dust generation.

According to an aspect of the present disclosure, a processing apparatus configured to separate a multilayer material in which a curable composition is sandwiched between a first member and a second member facing each other, includes a first holding unit configured to suction and hold a first surface of the multilayer material, a second holding unit configured to suction and hold a second surface facing the first surface of the multilayer material, and a deformation mechanism, wherein at least one of the first holding unit and the second holding unit is configured to suction and hold the multilayer material via a flexible member, and wherein the deformation mechanism is configured to deform at least a portion of the flexible member so as to form a start point of separation in the multilayer material.

Further objects or other aspects of the present disclosure will become apparent from the following description of exemplary embodiments with reference to the attached drawings.

Further features of the present disclosure will become apparent from the following description of exemplary embodiments with reference to the attached drawings.

### BRIEF DESCRIPTION OF THE DRAWINGS

FIGS. 1A and 1B are diagrams illustrating a processing apparatus according to an exemplary embodiment of the subject innovation.

FIGS. 2A and 2B are diagrams illustrating a multilayer material, according to an exemplary embodiment of the subject innovation.

FIGS. 3A and 3B are diagrams illustrating a relationship among the multilayer material, a flexible member, and a deformation mechanism, according to an exemplary embodiment of the subject innovation.

FIGS. 4A, 4B, and 4C are diagrams illustrating a method for releasing, according to an exemplary embodiment of the subject innovation.

FIGS. 5A, 5B, and 5C are diagrams illustrating examples of the flexible member, according to an exemplary embodiment of the subject innovation.

FIGS. 6A and 6B are diagrams illustrating a processing apparatus according to a second exemplary embodiment, according to an exemplary embodiment of the subject innovation.

FIG. 7 is a flowchart of a molding method according to a third exemplary embodiment, according to an exemplary embodiment of the subject innovation.

### DESCRIPTION OF THE EMBODIMENTS

Hereinafter, exemplary embodiments of the present disclosure will be described in detail with reference to the attached drawings.

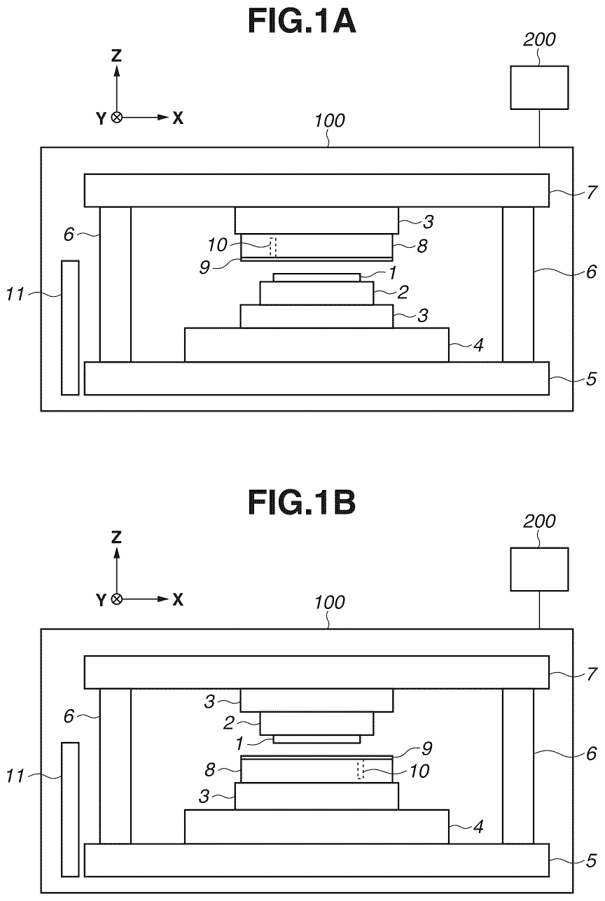

FIGS. 1A and 1B are diagrams illustrating a processing apparatus 100 according to a first exemplary embodiment. In FIGS. 1A and 1B, a Z-axis direction is defined as a vertical direction, and an XY direction orthogonal to the Z-axis direction is defined as a horizontal direction. As illustrated in FIG. 1A, the processing apparatus 100 includes a substrate holding unit (second holding unit) 2 that holds a substrate, a template drive unit (first drive unit) 3 that drives a template along a Z axis, a first surface plate 4, a base 5, first columns 6, a second surface plate 7, a first holding unit 8, a flexible member 9, and a deformation mechanism 10. The processing apparatus 100 further includes a member conveyance unit 11 and a control unit 200.

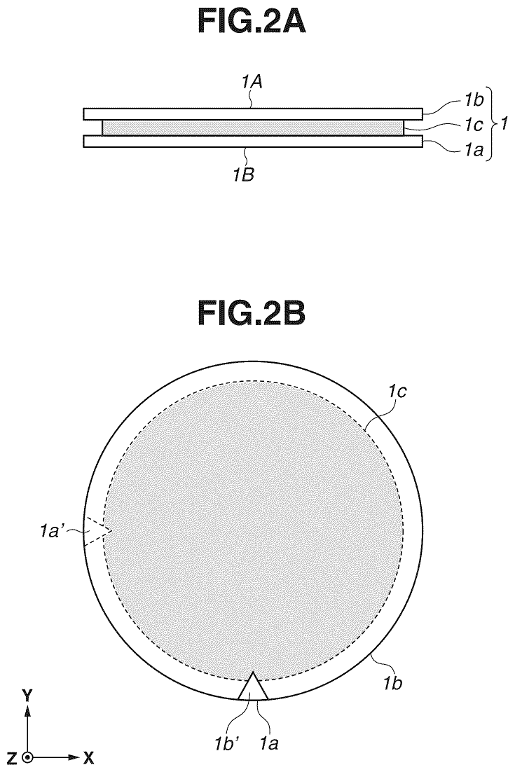

First, a multilayer material 1 will be described. The multilayer material 1 is formed of a substrate 1a, a template 1b, and a composition 1c as illustrated in FIG. 2A. After the composition 1c is placed on a surface of the substrate 1a, the composition 1c is molded by the template 1b. The composition 1c is a curable composition (ultraviolet curable resin) that is cured by ultraviolet rays, for example, and is cured by being irradiated with ultraviolet rays. However, the composition 1c is not limited to this example and may be cured by an electromagnetic wave other than the ultraviolet rays, by heat, or by any other means. The template 1b and the composition 1c are separated by the processing apparatus 100. Separating the template 1b from the composition 1c is referred to as releasing.

As a material for the substrate 1a, for example, glass, ceramics, metal, semiconductor, resin, or the like can be used. As necessary, a member made of a material different from that of the substrate may be provided on the surface of the substrate 1a. The substrate 1a is made of a silicon wafer, a compound semiconductor wafer, or quartz glass, for example. The substrate 1a may be a glass substrate for manufacturing a replica mask from a master mask by an imprinting process.

The template 1b has a surface that contacts the composition 1c. By the surface contacting the composition 1c, the composition 1c is molded so as to copy the contact surface. The template 1b is desirably a member that has a flat surface as the contact surface, i.e., what is called a super straight, or a member that has an uneven pattern on the contact surface, such as a mold for imprinting. In the case of the super straight, the template 1b is formed of a quartz or borosilicate glass wafer or the like having a flat surface of a size as large as the substrate, and can have a thickness in a range of 0.3 mm to 1.0 mm, for example.

One surface of the multilayer material 1 is referred to as a first surface 1A, and the other surface of the multilayer material 1 is referred to as a second surface 1B. In FIG. 2A, the first surface 1A corresponds to the surface of the template 1b, and the second surface 1B corresponds to the surface of the substrate 1a. Alternatively, the first surface 1A may constitute the surface of the substrate 1a, and the second surface 1B may constitute the surface of the template 1b. FIG. 2B is a top view of the multilayer material 1. The substrate 1a has a V-notch as a substrate positioning mark 1a′, but may have another mark such as an orientation flat. Similarly, the template 1b has a V-notch as a template positioning mark 1b′, but may have another mark such as an orientation flat or may have no mark. In FIG. 2B, the template positioning mark 1b′ is arranged at a position rotated by 90° From the substrate positioning mark 1a′, but the positional relationship thereof is not limited to 90° as long as the template positioning mark 1b′ does not overlap the substrate positioning mark 1a′.

Subsequently, each member constituting the processing apparatus 100 is described with reference to FIG. 1A.

The member conveyance unit 11 includes a conveyance hand or the like and delivers the multilayer material 1 to the second holding unit 2 from a position (not illustrated) outside or inside of the processing apparatus 100. Here, it is assumed that the composition 1c constituting the multilayer material 1 is already cured.

The second holding unit 2 holds the multilayer material 1 by vacuum suction, for example. However, the means of holding the multilayer material 1 is not limited thereto. For example, the second holding unit 2 may hold the multilayer material 1 by electrostatic adsorption.

The flexible member 9 is configured to be capable of holding the multilayer material 1, and the flexible member 9 is held by the first holding unit 8. The means of holding the multilayer material 1 by the flexible member 9 is desirably vacuum suction, for example. In this case, the flexible member 9 has a plurality of flow paths therein, and one outlet of each of the flow paths is formed on the surface that holds the multilayer material 1 and the other outlet thereof is formed on the surface that is held by the first holding unit 8.

The first holding unit 8 also has a plurality of flow paths therein, and one outlet of each of the flow paths is connected to an external vacuum source and the other outlet is formed on the surface that holds the flexible member 9. At least one of outlets formed on the surface that holds the flexible member 9 is connected to the outlet of the flow path formed in the flexible member 9 when the first holding unit 8 holds the flexible member 9.

According to this method, the external vacuum source is coupled to the flexible member 9 via the first holding unit 8 so that the flexible member 9 can hold the multilayer material 1 by vacuum suction. Further, the means for the first holding unit 8 to hold the flexible member 9 may be vacuum suction, or the first holding unit 8 may fix the flexible member 9 by fastening or adhesion.

The first holding unit 8 and the second holding unit 2 are connected to the second surface plate 7 and the first surface plate 4, respectively, via the first drive unit 3. Alternatively, either the first holding unit 8 or the second holding unit 2 may be connected to the first drive unit 3. More specifically, if only the first holding unit 8 is connected to the first drive unit 3, the second holding unit 2 is fixed to the first surface plate 4, and if only the second holding unit 2 is connected to the first drive unit 3, the first holding unit 8 is fixed to the second surface plate 7.

It is to be noted that, in the present exemplary embodiment, merely the positional relationships among the multilayer material 1, the flexible member 9, the first holding unit 8, and the second holding unit 2 are defined. Thus, a configuration illustrated in FIG. 1B is also conceivable. In this case, the first holding unit 8 and the second holding unit 2 are connected via the first drive unit 3 to the first surface plate 4 and the second surface plate 7, respectively. Alternatively, either the first holding unit 8 or the second holding unit 2 may be connected to the first drive unit 3.

The first drive unit 3 includes an actuator such as a linear motor, a rotary motor, or a voice coil motor, a ball screw, a linear guide, and the like, for example, and drives both the first holding unit 8 and the second holding unit 2 or either of the holding units in a Z direction. Further, the first drive unit 3 may include an additional actuator to drive the holding unit(s) also in an X direction and a Y direction, or may be configured so that the holding unit(s) is/are rotatable around an X axis, a Y axis, and the Z axis.

The deformation mechanism 10 is connected to the flexible member 9 and a fixing part (not illustrated), the first holding unit 8, or the second holding unit 2, and deforms at least a portion of the flexible member 9. The deformation mechanism 10 may include an actuator such as a linear motor, a rotary motor, a voice coil motor, or a piezoelectric element and a mechanical element such as a ball screw or a linear guide, or may be configured to deform the flexible member 9 by vacuum suction. However, the deformation mechanism 10 desirably includes a set of an electromagnet and a ferromagnetic material from a viewpoint of preventing dust generation or the like.

The ferromagnetic material is bonded and fixed to or embedded in the flexible member 9, and the electromagnet is arranged immediately above or below the ferromagnetic material. When electric current flows through the electromagnet, a magnetic field is generated, and a magnetic force (attractive force or repulsive force) is generated between the electromagnet and the ferromagnetic material. Using the magnetic force avoids mechanical wear and reduces the risk of dust generation.

The first surface plate 4 is placed on the base 5, and the first columns 6 are arranged to support the second surface plate 7.

The control unit 200 includes a processor such as a central processing unit (CPU), a storage unit such as a random access memory (RAM), a read only memory (ROM), and a hard disk device (HDD), and an interface unit for connecting the processor with an external device. The interface unit includes a communication interface that communicates with a host computer. The host computer is a computer that controls an entire factory or a region of the factory where the processing apparatus 100 is installed, for example. The processor executes programs stored in the storage unit to control operations of the processing apparatus 100. The control unit 200 may include a plurality of circuit boards. The control unit 200 may be entirely or partially arranged in a rack inside a chamber (housing) of the processing apparatus 100 or may be arranged outside of the chamber.

The control unit 200 controls the operations of the processing apparatus 100. The operations of the processing apparatus 100 herein include operations of the units. The control unit 200 controls the operations of the first drive unit 3 and the deformation mechanism 10.

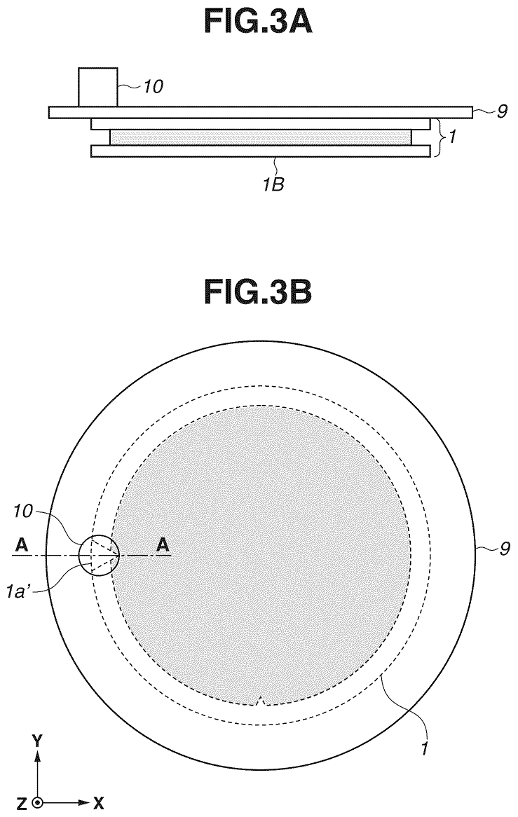

FIG. 3A illustrates an example of a relationship among the multilayer material 1, the flexible member 9, and the deformation mechanism 10. Although not illustrated in the drawing, the second holding unit 2 and the first holding unit 8 hold the second surface 1B of the multilayer material 1 and the flexible member 9, respectively. It is to be noted that the flexible member 9 is to hold the first surface 1A of the multilayer material 1, and as described above, the flexible member 9 may hold the substrate 1a or the template 1b.

The deformation mechanism 10 is desirably arranged immediately above or below the outer periphery of the multilayer material 1. This is advantageous in releasing the template 1b of the multilayer material 1 from the cured composition 1c as described below. However, the arrangement of the deformation mechanism 10 is not limited to this, and the deformation mechanism 10 may not be arranged along the outer periphery of the multilayer material 1.

FIG. 3B is a top view of the multilayer material 1, the flexible member 9, and the deformation mechanism 10.

The deformation mechanism 10 is desirably arranged along the outer periphery of the multilayer material 1 as described above. More specifically, as illustrated in FIG. 3B, the deformation mechanism 10 is desirably arranged immediately above or below the substrate positioning mark 1a′ or the template positioning mark 1b′ provided on the outer periphery of the multilayer material 1. This is more advantageous in releasing the template 1b of the multilayer material 1 from the cured composition 1c because a contact area between the template 1b and the composition 1c is small around the substrate positioning mark 1a′ or the template positioning mark 1b′.

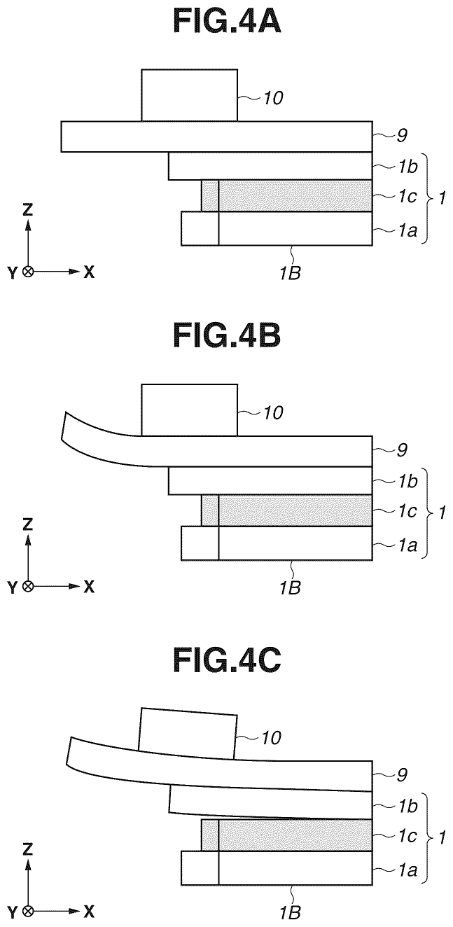

To describe a releasing method, FIGS. 4A to 4C illustrate a cross section A-A of FIG. 3B. Although not illustrated in the drawings, the second holding unit 2 and the first holding unit 8 hold the second surface 1B of the multilayer material 1 and the flexible member 9, respectively. Both the second holding unit 2 and the first holding unit 8 or either of the holding units are connected to the first drive unit 3.

In FIGS. 4A to 4C, the template 1b of the multilayer material 1 is held by the flexible member 9. Alternatively, the substrate 1a may be held by the flexible member 9. FIG. 4A illustrates a state where the first drive unit 3 and the deformation mechanism 10 are not operating, and the flexible member 9 and the multilayer material 1 are in a neutral state. To start the releasing of the multilayer material 1, the first drive unit 3 is operated to move the second holding unit 2 and the first holding unit 8 (not illustrated) away from each other in the Z direction. Accordingly, the flexible member 9 deforms as illustrated in FIG. 4B, for example. At that time, tensile stress is substantially evenly applied to the flexible member 9 and the multilayer material 1.

The releasing occurs at a place where the tensile stress surpasses a condensation stress acting between the template 1b and the composition 1c. Thus, in the state of FIG. 4B, if the tensile stress is made larger than the condensation stress at a certain point, the tensile stress becomes evenly large on the entire surface of the multilayer material 1, and the start point of separation (releasing) is incidentally determined. In addition, a force necessary for releasing becomes large. Thus, the deformation mechanism 10 is operated as illustrated in FIG. 4C. This makes it possible to locally increase the tensile stress and generate the start point of releasing at a certain place. Further, if the deformation mechanism 10 is arranged immediately above or below the substrate positioning mark 1a′ or the template positioning mark 1b′, it is possible to more efficiently generate the start point of releasing.

After the generation of the start point, as the contact area between the template 1b and the composition 1c gradually becomes smaller, the tensile stress becomes larger, and the force necessary for releasing gradually becomes smaller, whereby it is possible to complete the releasing with a relatively small force. After the generation of the start point of releasing, the first drive unit 3 is further operated to advance and complete the releasing. In this case, the first drive unit 3 is operated and then the deformation mechanism 10 is operated to generate the start point of releasing. Alternatively, the deformation mechanism 10 may be operated and then the first drive unit 3 may be operated to generate the start point of releasing.

In generating the start point of releasing, a local force generated by the deformation mechanism 10 is to be efficiently transferred to the template 1b. In addition, the multilayer material 1 is not to fall off from the flexible member 9.

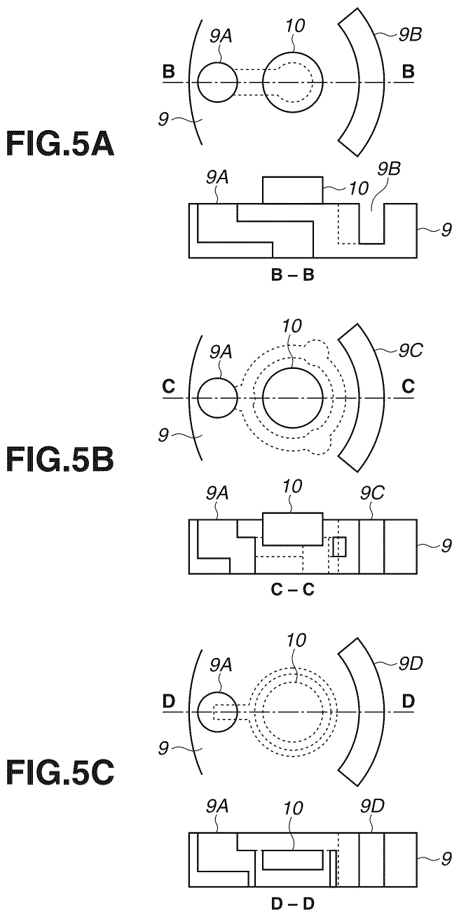

Thus, FIGS. 5A to 5C illustrate examples of means by which the flexible member 9 efficiently holds the multilayer material 1 and generates the start point of releasing. FIGS. 5A to 5C illustrate only a portion of the flexible member 9 and the deformation mechanism 10. The flexible member 9 illustrated in FIG. 5A is provided with a thin portion 9B that surrounds a portion of the periphery of the deformation mechanism 10. This increases shear stress that deforms the flexible member 9 at the thin portion 9B and increases displacement of the periphery of the deformation mechanism 10. The deformation mechanism 10 is bonded and fixed to the surface of the flexible member 9. A flow path 9A is connected immediately below the deformation mechanism 10, and a vacuum suction hole is provided. Accordingly, the displacement of the deformation mechanism 10 and the local displacement of the template 1b become substantially identical so that the force of the deformation mechanism 10 can be transferred in an efficient manner.

The flexible member 9 illustrated in FIG. 5B is provided with a cut out portion 9C that surrounds a portion of the periphery of the deformation mechanism 10. This increases the shear stress that deforms the flexible member 9 around the cut out portion 9C and increases the displacement of the periphery of the deformation mechanism 10. The deformation mechanism 10 is bonded and fixed to a recessed portion of the flexible member 9. In this case, since it is difficult to provide a vacuum suction hole immediately below the deformation mechanism 10, a vacuum suction hole may be arranged so as to annularly surround the periphery of the deformation mechanism 10. Accordingly, the displacement of the deformation mechanism 10 and the local displacement of the template 1b become substantially identical so that the force of the deformation mechanism 10 can be transferred in an efficient manner.

The flexible member 9 illustrated in FIG. 5C is provided with a dissimilar material portion 9D that surrounds a portion of the periphery of the deformation mechanism 10. The dissimilar material portion 9D may be fixed to another region by adhesion or may be integrated with another region by fusion. In this example, the dissimilar material portion 9D is desirably more flexible than the other region. This increases the deformation of the flexible member 9 at the dissimilar material portion 9D due to the shear stress, and increases the displacement of the periphery of the deformation mechanism 10. The deformation mechanism 10 is fully embedded in the flexible member 9. The shape of the vacuum suction hole in this case may be annular so as to surround the periphery of the deformation mechanism 10. Accordingly, the displacement of the deformation mechanism 10 and the local displacement of the template 1b become substantially identical so that the force of the deformation mechanism 10 can be transferred in an efficient manner.

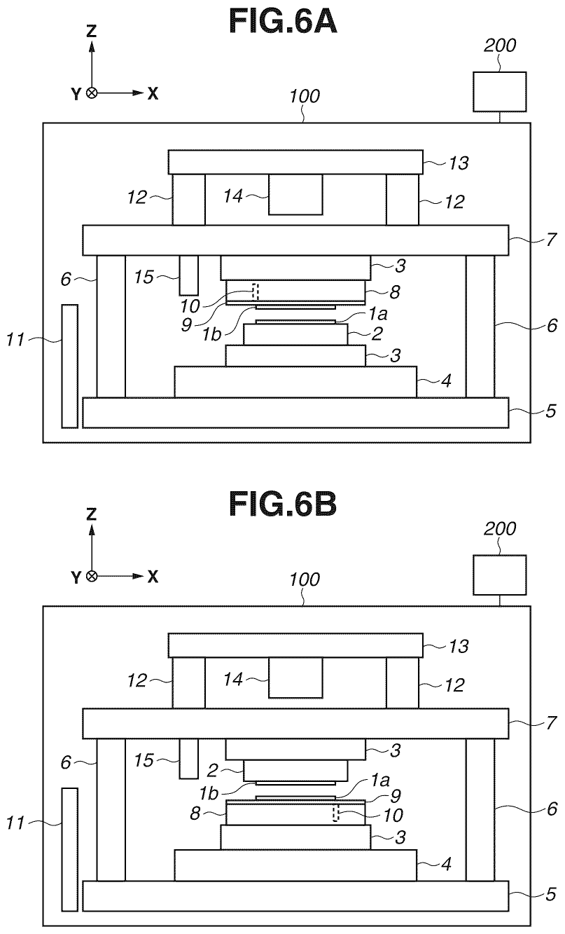

FIGS. 6A and 6B are diagrams illustrating a processing apparatus 100 according to a second exemplary embodiment. In FIGS. 6A and 6B, a Z-axis direction is defined as a vertical direction, and an XY direction orthogonal to the Z-axis direction is defined as a horizontal direction. As illustrated in FIG. 6A, the processing apparatus 100 includes a second holding unit 2, a first drive unit 3, a first surface plate 4, a base 5, first columns 6, a second surface plate 7, a first holding unit 8, a flexible member 9, and a deformation mechanism 10. The processing apparatus 100 further includes a member conveyance unit 11, second columns 12, a top plate 13, a light source 14, a composition supply unit 15, and a control unit 200.

The member conveyance unit 11 includes at least one conveyance hand or the like and delivers a substrate 1a to the second holding unit 2 and delivers a template 1b to the flexible member 9 from outside of the processing apparatus 100. At this time, a composition 1c may be arranged or may not be arranged on the substrate 1a.

The second holding unit 2 holds the substrate 1a by vacuum suction, for example. However, the present disclosure is not limited thereto. For example, the second holding unit 2 may hold the multilayer material 1 by electrostatic adsorption.

The flexible member 9 is held by the first holding unit 8. The means of holding the template 1b by the flexible member 9 to hold is desirably vacuum suction, for example. In this case, the flexible member 9 has a plurality of flow paths therein, and one outlet of each of the flow paths is formed on the surface that holds the template 1b and the other outlet thereof is formed on the surface that is held by the first holding unit 8. The first holding unit 8 also has a plurality of flow paths therein, and one outlet of each of the flow paths is connected to an external vacuum source and the other outlet is formed on the surface that holds the flexible member 9. At least one of outlets formed on the surface that holds the flexible member 9 is connected to the outlet of the flow path formed in the flexible member 9 when the first holding unit 8 holds the flexible member 9. According to this method, the external vacuum source is coupled to the flexible member 9 via the first holding unit 8 so that the flexible member 9 can hold the template 1b by vacuum suction. Further, the means for the first holding unit 8 to hold the flexible member 9 may be vacuum suction, or the first holding unit 8 may fix the flexible member 9 by fastening or adhesion.

The first holding unit 8 and the second holding unit 2 are connected to the second surface plate 7 and the first surface plate 4, respectively, via the first drive unit 3. Alternatively, only the second holding unit 2 may be connected to the first drive unit 3. More specifically, if only the second holding unit 2 is connected to the first drive unit 3, the first holding unit 8 is fixed to the second surface plate 7.

It is to be noted that, in the present exemplary embodiment, merely the positional relationships among the substrate 1a, the flexible member 9, the first holding unit 8, and the second holding unit 2 are defined. Thus, a configuration illustrated in FIG. 6B is also conceivable. In this case, the first holding unit 8 and the second holding unit 2 are connected via the first drive unit 3 to the first surface plate 4 and the second surface plate 7, respectively. Alternatively, only the first holding unit 8 may be connected to the first drive unit 3.

The first drive unit 3 includes an actuator such as a linear motor, a rotary motor, or a voice coil motor, a ball screw, a linear guide, and the like, for example, and drives both the first holding unit 8 and the second holding unit 2 or either of the holding units in a Z direction, and drives the second holding unit 2 in an X direction. Further, the first drive unit 3 may include an additional actuator to drive the first holding unit 8 also in the X direction and the Y direction and drive the second holding unit 2 in the Y direction, or may be configured so that the holding units are rotatable around an X axis, a Y axis, and a Z axis.

The first drive unit 3 can move the second holding unit 2 holding the substrate 1a immediately below the composition supply unit 15, and the composition supply unit 15 supplies the composition 1c onto the substrate 1a. However, if the composition 1c has already been supplied to the substrate 1a delivered by the member conveyance unit 11, the first drive unit 3 may not move the second holding unit 2 immediately below the composition supply unit 15.

Further, if the composition 1c has been supplied onto the substrate 1a, the first drive unit 3 brings the second holding unit 2 and the first holding unit 8 close to each other in the Z direction. Accordingly, the composition 1c on the substrate 1a and the template 1b are brought into contact with each other to mold the composition 1c into its shape using the template 1b.

The light source 14 generates light in the wavelength with which the composition 1c is cured. In this case, the light source 14 is provided because the composition 1c is assumed to be a light-curing resin. If the composition 1c is a thermosetting resin, a heat source may be arranged instead of the light source 14. The light generated by the light source 14 is emitted toward the composition 1c molded using the template 1b, and the composition 1c is cured. Accordingly, the multilayer material 1 formed of the substrate 1a, the composition 1c, and the template 1b is formed.

The deformation mechanism 10 is connected to the flexible member 9 a fixing part (not illustrated), the first holding unit 8, or the second holding unit 2, and deforms at least a portion of the flexible member 9. The deformation mechanism 10 may include an actuator such as a linear motor, a rotary motor, a voice coil motor, or a piezo element, and a mechanical element such as a ball screw or a linear guide, or may be configured to deform the flexible member 9 by vacuum suction. However, the deformation mechanism 10 desirably include a set of an electromagnet and a ferromagnetic material from a viewpoint of preventing dust generation or the like. The ferromagnetic material is bonded and fixed to or embedded in the flexible member 9, and the electromagnet is arranged immediately above or below the ferromagnetic material. When electric current flows through the electromagnet, a magnetic field is generated, and a magnetic force (attractive force or repulsive force) is generated between the electromagnet and the ferromagnetic material. Using the magnetic force avoids mechanical wear and reduces the risk of dust generation.

The first surface plate 4 is placed on the base 5, and the first columns 6 are arranged to support the second surface plate 7.

The control unit 200 includes a processor such as a CPU, a storage unit such as a RAM, a ROM, and an HDD, and an interface unit for connecting the processor with an external device. The interface unit includes a communication interface that communicates with a host computer. The host computer is a computer that controls the entire factory or a region of the factory where the processing apparatus 100 is installed, for example. The processor executes programs stored in the storage unit to control the operations of the processing apparatus 100. The control unit 200 may include a plurality of circuit boards. The control unit 200 may be entirely or partially arranged in a rack inside the chamber (housing) of the processing apparatus 100 or may be arranged outside of the chamber.

The control unit 200 controls the operations of the processing apparatus 100. The operations of the processing apparatus 100 herein include operations of the units. The control unit 200 controls the operations of the first drive unit 3 and the deformation mechanism 10, and performs releasing by a method similar to that of the first exemplary embodiment.

Next, a molding method according to a third exemplary embodiment of the present disclosure will be described. Molding steps using the processing apparatus 100 described above is classified into a first step, a second step, and a third step.

The first step is a step of driving the deformation mechanism 10 to deform a portion of the flexible member 9 holding the multilayer material 1 and generate a start point of releasing between the template 1b and the composition 1c.

The second step is a step of driving the first drive unit 3 to move the second holding unit 2 and the first holding unit 8 away from each other in the Z direction to advance the start point of releasing generated between the template 1b and the composition 1c to complete the releasing.

The third step is a step executed before the first step and the second step as necessary, and is a step of molding the composition 1c supplied on the substrate 1a using the template 1b and curing the composition 1c with light emitted from the light source 14 to form the multilayer material 1.

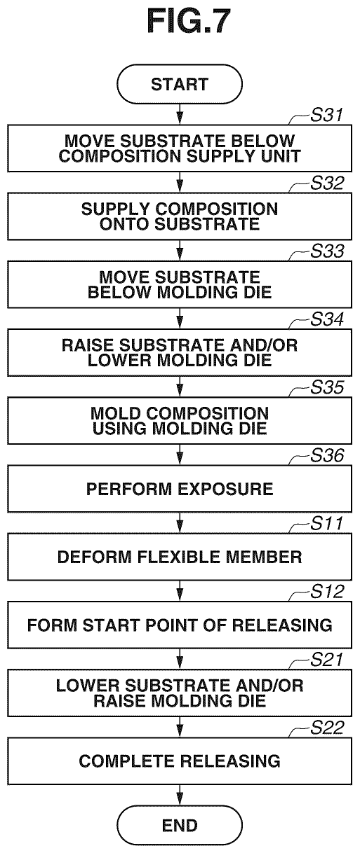

FIG. 7 is a flowchart of the molding method. The flowchart herein is based on a case where the substrate 1a not supplied with the composition 1c is conveyed by the member conveyance unit 11 from outside of the processing apparatus 100. If the member conveyed by the member conveyance unit 11 is the multilayer material 1, steps S31 to S35 are skipped, and if the member conveyed by the member conveyance unit 11 is the substrate 1a supplied with the composition 1c, steps S31 to S33 are skipped.

In step S31, the first drive unit 3 is driven to move the substrate 1a immediately below the composition supply unit 15. The composition supply unit 15 can supply the composition 1c onto the substrate 1a, and in step S32, the composition supply unit 15 supplies the composition 1c onto the substrate 1a. While the composition supply unit 15 is supplying the composition 1c, the first drive unit 3 may be driven to continue to move the substrate 1a to a predetermined position, or the substrate 1a may be stopped. Upon completion of the supply of the composition 1c onto the substrate 1a, in step S33, the first drive unit 3 is driven to move the substrate 1a immediately below the template 1b.

In step S34, the first drive unit 3 raises the substrate 1a and/or lowers the template 1b to bring the substrate 1a and the template 1b close to each other. In step S35, the first drive unit 3 is further driven to press the template 1b against the composition 1c on the substrate 1a so that the composition 1c is molded into its shape. When the composition 1c is molded, in step S36, the composition 1c is cured with light emitted from the light source 14 to form the multilayer material 1.

In step S11, the deformation mechanism 10 is driven to deform a portion of the flexible member 9 holding the first surface 1A of the multilayer material 1. Accordingly, in step S12, a start point of releasing is generated between the template 1b and the composition 1c. Prior to this, the first drive unit 3 may be driven to bring the second holding unit 2 and the first holding unit 8 slightly away from each other in the Z direction to generate tension on the flexible member 9 and the multilayer material 1. After the generation of the start point of releasing between the template 1b and the composition 1c, in step S21, the first drive unit 3 is driven to lower the substrate 1a and/or raise the template 1b. Accordingly, in step S22, the start point of releasing generated between the template 1b and the composition 1c is advanced and the releasing is completed. Then, the processing is ended.

Hereinafter, the exemplary embodiments of the present disclosure have been described. However, the present disclosure is not limited to these exemplary embodiments and can be modified and changed in various manners within the scope of the gist of the present disclosure.

More specifically, with the present disclosure, it is possible to provide a processing apparatus that is advantageous in forming the start point of separation while preventing dust generation.

The present disclosure is not limited to the above-described exemplary embodiments, and various changes and modifications can be made without departing from the spirit and scope of the present disclosure. Therefore, the claims are appended to make public the scope of the present disclosure.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-040175, filed Mar. 14, 2023, which is hereby incorporated by reference herein in its entirety.

What is claimed is:

1. A processing apparatus configured to separate a multilayer material in which a curable composition is sandwiched between a first member and a second member facing each other, the processing apparatus comprising:
a first holding unit configured to suction and hold a first surface of the multilayer material;
a second holding unit configured to suction and hold a second surface facing the first surface of the multilayer material; and
a deformation mechanism,
wherein at least one of the first holding unit and the second holding unit is configured to suction and hold the multilayer material via a flexible member, and
wherein the deformation mechanism is configured to deform at least a portion of the flexible member so as to form a start point of separation in the multilayer material.

2. The processing apparatus according to claim 1, wherein the first member is a substrate and the second member is a template used to mold the curable composition.

3. The processing apparatus according to claim 2,
wherein the first holding unit is a substrate holding unit configured to suction and hold a bottom surface of the substrate, and
wherein the second holding unit is a template holding unit configured to suction and hold an upper surface of the template.

4. The processing apparatus according to claim 3,
wherein at least one of the template holding unit and the substrate holding unit is configured to suction and hold at least a portion of an outer peripheral part of the template via the flexible member or at least a portion of an outer peripheral part of the substrate via the flexible member, and
wherein the deformation mechanism is configured to partially deform the flexible member so as to form a start point of releasing at which the curable composition and the template are separated from each other.

5. The processing apparatus according to claim 3,
wherein the flexible member is provided to the template holding unit and has suction holes for suctioning and holding the template, and
wherein at least one of the suction holes is positioned immediately below the deformation mechanism.

6. The processing apparatus according to claim 3,
wherein the flexible member is provided to the template holding unit and has suction holes for suctioning and holding the template, and
wherein, when being viewed from a direction perpendicular to a surface of the flexible member holding the template, some of the suction holes are positioned so as to annularly surround the deformation mechanism.

7. The processing apparatus according to claim 3,
wherein the flexible member has an annular suction hole for suctioning and holding the template, and
wherein, when being viewed from a direction perpendicular to a surface of the flexible member holding the template, the suction hole is positioned so as to annularly surround the deformation mechanism.

8. The processing apparatus according to claim 1, further comprising:
at least one first drive unit configured to relatively move the first holding unit and the second holding unit in a direction orthogonal to the first surface or the second surface; and
a control unit configured to control the first drive unit and the deformation mechanism.

9. The processing apparatus according to claim 1, wherein the deformation mechanism is positioned immediately above an outer peripheral part of the multilayer material at a time of driving.

10. The processing apparatus according to claim 1, wherein the deformation mechanism is positioned immediately above a cutout provided in an outer peripheral part of the multilayer material at a time of driving.

11. The processing apparatus according to claim 1, wherein at least one region of the flexible member is more easily deformed than another region.

12. The processing apparatus according to claim 1, wherein at least one region of the flexible member is thinner than another region.

13. The processing apparatus according to claim 1, wherein at least one region of the flexible member is cut out.

14. The processing apparatus according to claim 1, wherein a material of at least one region of the flexible member is different from a material of another region.

15. The processing apparatus according to claim 1, wherein the deformation mechanism includes a set of an electromagnet and a ferromagnetic material.

16. The processing apparatus according to claim 15, wherein the ferromagnetic material is bonded to a surface of the flexible member.

17. The processing apparatus according to claim 15, wherein the ferromagnetic material is embedded in the flexible member.

18. A processing method for separating a multilayer material in which a curable composition is sandwiched between a first member and a second member facing each other, the processing method comprising:
suctioning and holding a first surface of the multilayer material by a first holding unit;
suctioning and holding a second surface facing the first surface of the multilayer material by a second holding unit; and
forming a start point of separation in the multilayer material,
wherein at least one of the first holding unit and the second holding unit is configured to suction and hold the multilayer material via a flexible member, and
wherein the forming includes deforming at least a portion of the flexible member so as to form the start point of separation in the multilayer material.

19. The processing method according to claim 18, further comprising, after the forming, relatively moving the first holding unit and the second holding unit in a direction orthogonal to the first surface or the second surface to complete releasing.

20. The processing method according to claim 18, wherein the first member is a substrate and the second member is a template used to mold the curable composition.

21. A method for manufacturing an article, comprising:
molding a curable composition on a substrate by using the processing apparatus according to claim 1;
processing the substrate on which the composition has been molded in the molding; and
manufacturing the article from the processed substrate.
